(19) United States
(12) Patent Application Publication
(10) Pub. No.: US 2009/0159984 A1
(43) Pub. Date: Jun. 25, 2009

(54) Semiconductor Device and Method for Manufacturing the Same

(76) Inventor: Yeo Cho Yoon, Yeongdeungpo-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/145,884

(22) Filed: Jun. 25, 2008

(30) Foreign Application Priority Data
Dec. 22, 2007 (KR) 10-2007-0135957

(51) Int. Cl. H01L 27/06; H01L 21/8249

(52) U.S. Cl. 257/378; 438/207; 257/E27.015; 257/E21.696

(57) ABSTRACT

A semiconductor device and a method for manufacturing the same are provided. An n-well region can be formed on a semiconductor substrate, and a base contact region can be formed on the n-well region. An emitter contact region, a collector contact region, and a p-base region can also be formed on the n-well. The emitter and collector contact regions can include n-type ions, and the base contact region and the p-base region can include p-type ions. Thus, the semiconductor device can include an n-channel metal oxide semiconductor transistor and an NPN bipolar transistor.

### CROSS-REFERENCE TO RELATED APPLICATION

The present application claims the benefit under 35 U.S.C. §119 of Korean Patent Application No. 10-2007-0135957, filed Dec. 22, 2007, which is hereby incorporated by reference in its entirety.

### BACKGROUND

A bipolar transistor, a type of semiconductor integrated device, is a semiconductor device with two PN junctions formed with a base, a collector, and an emitter on a silicon substrate. A bipolar transistor generally performs switching and amplification functions.

A bipolar transistor is typically configured with the collector enclosing the perimeter of the emitter, so that current flows from the emitter past the base to the collector. Additionally, the base has a dopant with a polarity different from that of a dopant of the emitter and collector. The resistance of the base can be selectively changed to control current flowing from the emitter to the collector.

### BRIEF SUMMARY

Embodiments of the present invention provide semiconductor devices with favorable electrical characteristics and methods for forming the semiconductor devices. According to embodiments, an NPN bipolar trench can be formed in a complementary metal oxide semiconductor (CMOS) device.

In one embodiment, a semiconductor device can include: a semiconductor substrate including an n-well; an n-channel metal oxide semiconductor (NMOS) transistor on the semiconductor substrate separated from the n-well by a device isolation layer; a p-base region on the n-well; a base contact region and an emitter contact region on the p-base region; and a collector region on the n-well; wherein the emitter contact region comprises n-type ions, and wherein the collector contact region comprises n-type ions, and wherein the base contact region comprises p-type ions, and wherein the p-base region comprises p-type ions.

In another embodiment, a method for manufacturing a semiconductor device can include: forming an n-well region on a semiconductor substrate; forming a gate on the semiconductor substrate separated from the n-well region by a device isolation layer; forming a base contact region on the n-well region; forming a source region and a drain region for the gate on the semiconductor substrate; forming an emitter contact region and a collector contact region on the n-well; and forming a p-base region on the n-well including on the base contact region and the emitter contact region; wherein the source region comprises n-type ions, and wherein the drain region comprises n-type ions, and wherein the emitter contact region comprises n-type ions, and wherein the collector contact region comprises n-type ions, and wherein the base contact region comprises p-type ions, and wherein the p-base region comprises p-type ions.

The details of one or more embodiments are set forth in the accompanying drawings and the description below. Other features will be apparent from the detailed description, the drawings, and the claims.

### BRIEF DESCRIPTION OF THE DRAWINGS

FIGS. 1 to 6 are cross-sectional views showing methods for manufacturing semiconductor devices according to embodiments of the present invention.

### DETAILED DESCRIPTION

Reference will now be made in detail to the embodiments of the present disclosure, examples of which are illustrated in the accompanying drawings.

When the terms “on” or “over” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

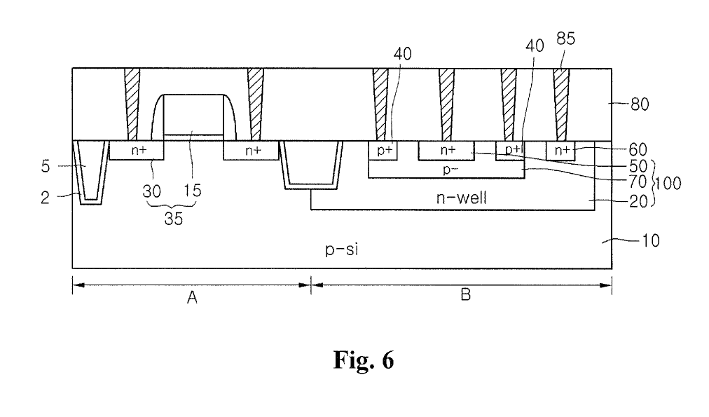

FIG. 6 is a cross-sectional view of a semiconductor device according to an embodiment of the present invention.

Referring to FIG. 6, a semiconductor device according to an embodiment can include a semiconductor substrate 10 with an n-well 20 and a device isolation layer 5; an n-channel metal oxide semiconductor (nMOS) transistor 35 including a source and a drain region 30 and a gate 15 formed on the semiconductor substrate 10; a base contact region 40, an emitter contact region 50, and a collector contact region 60 formed on the n-well 20; and a p-base region 70 formed on the n-well 20.

The semiconductor substrate 10 can be formed of, for example, a p-type silicon substrate, and the semiconductor substrate 10 can include additional layers, such as an epitaxial layer.

In an embodiment, an interlayer dielectric 80 including contacts 85 can be formed on the semiconductor substrate 10 including the nMOS transistor 35 and the NPN bipolar transistor 100. The contacts 85 can be respectively connected to the source and drain regions 30, the base contact region 40, the emitter contact region 50, and the collector contact region 60.

A thermal oxide layer 2 can be formed between the device isolation layer 5 and the semiconductor substrate 10.

The thermal oxide layer 2 can be formed to improve interfacial characteristics between the semiconductor substrate 10 and the dielectric of the device isolation layer 5.

The base contact region 40 and the emitter contact region 50 can be provided in the p-base region. The p-base region 70 can be formed on the n-well 20.

In an embodiment, the source and drain regions 30, the emitter contact region 50, and the collector contact region 60 can be formed with n-type ions, and the base contact region 40 and the p-base region 70 can be formed with p-type ions.

According to embodiments, the emitter contact region 50, the p-base region 70, and the n-well 20 form an NPN bipolar transistor 100.

Additionally, the p-base region 70 can be formed with p-type ions at a low concentration, and the base contact region 40 can be formed with a concentration of p-type ions higher than that of the p-base region 70 (i.e. at a high concentration).

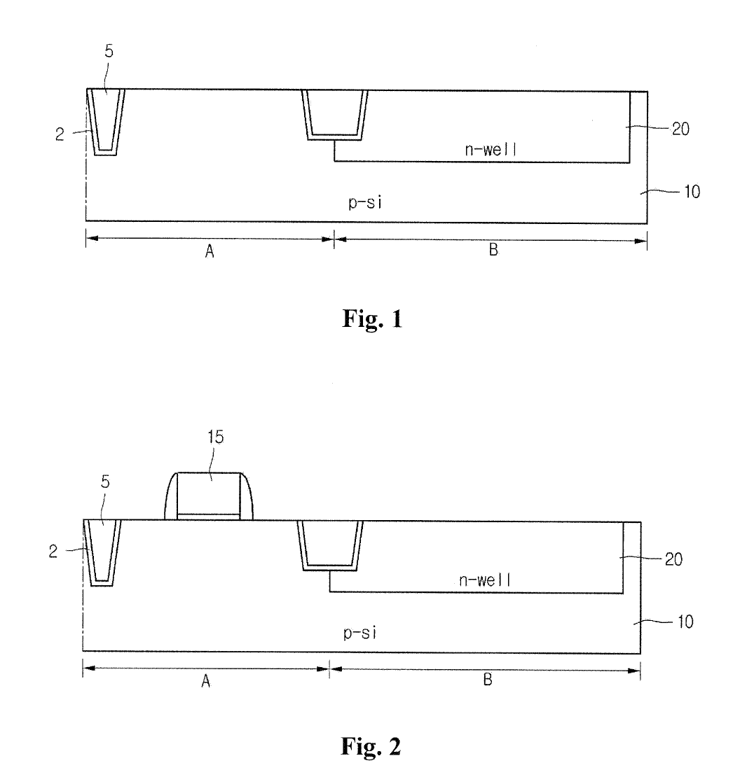

FIGS. 1 to 6 are cross-sectional views showing methods for manufacturing semiconductor devices according to embodiments of the present invention.

Referring to FIG. 1, an n-well 20 and a device isolation layer 5 can be formed on a semiconductor substrate 10.

In an embodiment, the device isolation layer 5 can be formed on the semiconductor substrate 10 and separating a first region (A) from a second region (B), and the n-well 20 can be formed on the second region (B) of the semiconductor substrate 10

The n-well 20 can be formed through any suitable process known in the art. For example, a first photoresist pattern can be formed on the first region (A), and a first ion implantation can be performed to form the n-well 20. The ions for the first ion implantation can be any suitable ions known in the art, for example, phosphorous (P) ions.

The first region (A) can be a region for forming an nMOS transistor, and the second region (B) can be a region for forming an NPN bipolar transistor.

The semiconductor substrate 10 can be formed of, for example, a p-type silicon substrate, and the semiconductor substrate 10 can include additional layers, such as an epitaxial layer.

Also, a first heat treating process can be performed on the semiconductor substrate 10 including the n-well 20 to activate ions implanted in the n-well 20.

During the first heat treating process, the ions implanted in the n-well 20 can be activated and any defects that may be present on the semiconductor substrate 10 can be repaired.

The device isolation layer 5 can be formed by patterning a trench in the semiconductor substrate 10. Then, a thermal oxide layer 2 can be formed in the trench, and the trench can be filled with a dielectric.

The thermal oxide layer 2 can be formed to improve interfacial characteristics between the semiconductor substrate 10 and the dielectric. However, in certain embodiments, the thermal oxide layer 2 may be omitted.

Referring to FIG. 2, a gate 15 can be formed on the semiconductor substrate 10 in the first region (A).

The gate 15 can be formed through any suitable process known in the art. For example, the gate can be formed of a first oxide layer pattern, a polysilicon pattern, and a spacer. A first oxide layer and a polysilicon layer can be formed on the semiconductor substrate 10 and patterned to form the first oxide layer pattern and the polysilicon pattern, respectively. In one embodiment, the spacer can be an oxide-nitride-oxide spacer. For example, an oxide-nitride-oxide (ONO) layer can be formed on the semiconductor substrate 10 including the first oxide layer pattern and the polysilicon pattern, and anisotropic etching can be performed to form the spacer. Embodiments of the spacer are not limited to the ONO structure, and can have, for example, an oxide-nitride (ON) structure.

Also, while not shown in the Figures, before the spacer is formed, a lightly doped drain (LDD) region can be formed on the semiconductor substrate 10 including the gate 15, to inhibit leakage of channel current.

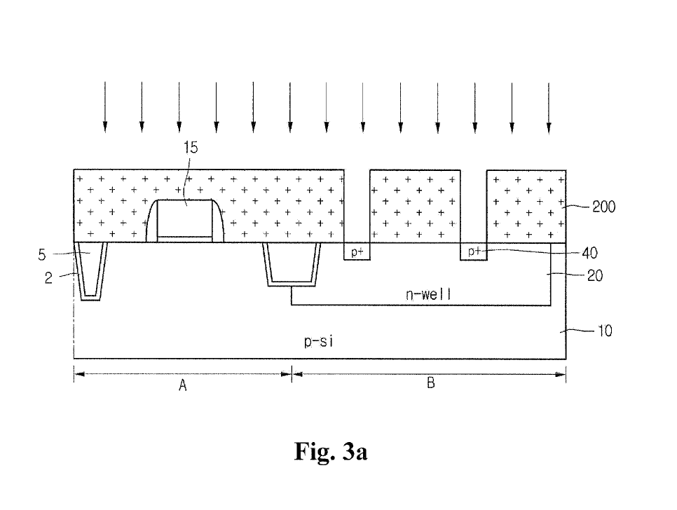

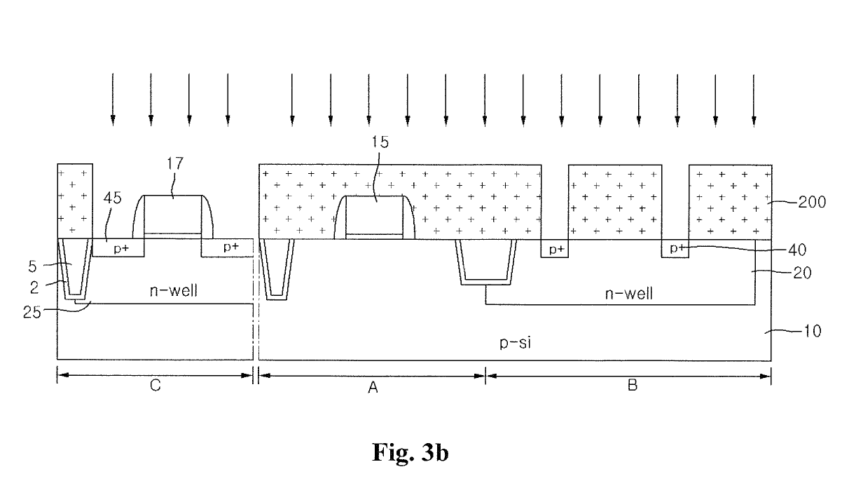

Referring to FIG. 3A, a second photoresist pattern 200 can be formed on the semiconductor substrate 10, and a second ion implantation can be performed to form a base contact region 40.

The base contact region 40 can be formed with, for example, a p-type ion.

The second ion implantation process can be performed using any suitable ion known in the art, for example, boron.

The base contact region 40 can be formed on the n-well 20 formed in the second region (B).

Referring to FIG. 3B, in one embodiment, the base contact region 40, can be simultaneously formed with source and drain regions 45 of a pMOS gate 17 formed on a third region (C). Thus, a separate mask would not be required during the second ion implantation when fabricating CMOS transistors.

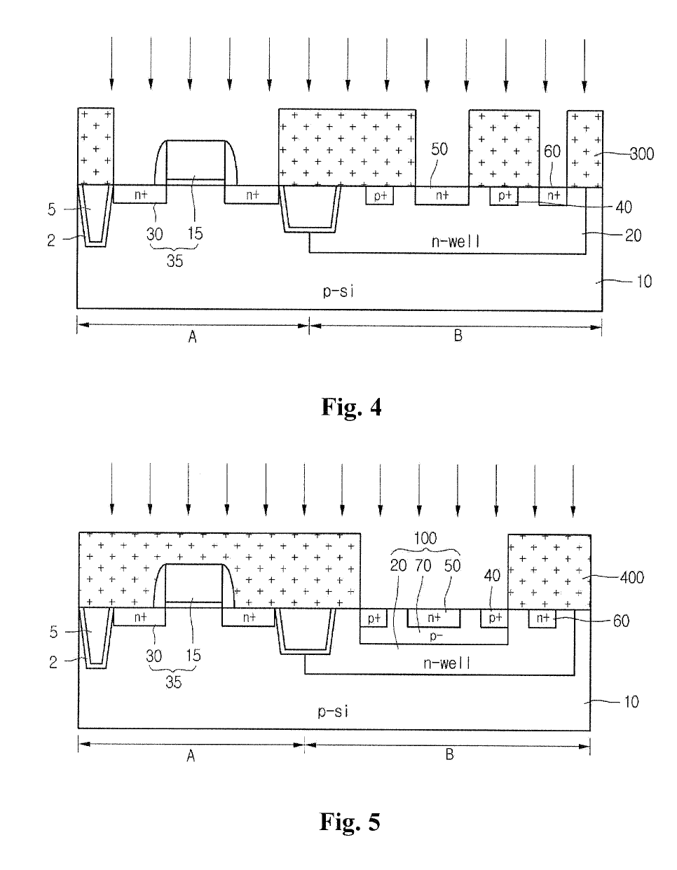

Next, referring to FIG. 4, a third photoresist pattern 300 can be formed on the semiconductor substrate 10, and a third ion implantation process can be performed to form an emitter contact region 50 and a collector contact region 60 in the second region (B) and source/drain regions 30 in the first region (A).

In an embodiment, the third ion implantation process can be performed to simultaneously form the source/drain regions 30, the emitter contact region 50, and the collector contact region 60. Thus, a separate mask would not be required during the third ion implantation.

The third ion implantation process can be performed using any suitable ions known in the art, for example, phosphorous (P) ions.

The source and drain regions 30, along with the gate 15 can form the nMOS transistor 35.

Also, the emitter contact region 50 and collector contact region 60 can be formed on the n-well 20 in the second region (B).

Referring to FIG. 5, a fourth photoresist pattern 400 can be formed on the semiconductor substrate 10, and a fourth ion implantation process can be performed to form a p-base region 70 in the n-well 20.

The fourth ion implantation process can be performed using any suitable ions known in the art, for example, boron ions. Also, the p-base region 70 can be lightly doped with p-type ions at a shallow depth, to help increase current gain.

While the depth of the p-base region 70 can be shallow, it can still be deeper than that of the emitter contact region 50 and the base contact region 40.

Also, in an embodiment, the base contact region 40 can be doped with a higher concentration of ions than the p-base region 70, to provide an ohmic contact with the base contact region 40 at a later stage.

In addition, in one embodiment, the p-base region 70 can be formed simultaneously with an electrostatic discharge (ESD) process for ESD protection during a CMOS transistor forming process. Thus, a separate mask would not be required when performing the fourth ion implantation process.

Then, a second heat treating process can be performed on the semiconductor substrate 10 to activate the source and drain regions 30, the base contact region 40, the emitter contact region 50, and the collector contact region 60.

According to embodiments of the present invention, an NPN bipolar transistor 100, can be formed of the emitter contact region 50, the p-base region 70, and the n-well 20.

The NPN bipolar transistor 100 including the p-base region 70 can help increase current gain compared to a PNP bipolar transistor.

Since electrons are majority carriers of the NPN bipolar transistor 100, better mobility is obtained versus a PNP bipolar transistor with holes as majority carriers. Thus, noise characteristics of the bipolar transistor 100 can be improved.

Also, by using the bipolar transistor 100 with superior flicker noise characteristics, the transistor can be used in a device with favorable phase noise characteristics of a voltage controlled oscillator (VCO) circuit.

Next, referring again to FIG. 6, an interlayer dielectric 80 including contacts 85 can be formed on the semiconductor substrate 10 including the nMOS transistor 35 and the NPN bipolar transistor 100.

The contacts 85 can be connected to the source and drain regions 30, the base contact region 40, the emitter contact region 50, and the collector contact region 60, and can be formed in the interlayer dielectric 80.

The contacts 85 can be formed by any suitable process known in the art. For example, contact holes can be formed in the interlayer dielectric 80 and filled with a metal material to form the contacts 85. The metal material can be any suitable material known in the art, for example tungsten (W).

Also, while not shown in the Figures, a metal wiring layer can be formed on the interlayer dielectric 80 including the contacts 85.

With the above-described semiconductor device and method of forming the same according to embodiments of the present invention, a semiconductor device formed of an nMOS transistor and an NPN bipolar transistor can be formed. An n-well, a p-base contact region, a base contact, an emitter contact, and a collector contact can be formed on a p-type semiconductor substrate with the nMOS transistor.

In one embodiment, source and drain regions of a pMOS transistor can be simultaneously formed with the base contact region, so that a separate mask would not required during ion implantation.

Also, according to certain embodiments, the emitter contact region and collector contact region can be simultaneously formed with the source/drain regions of the nMOS transistor, so that a separate mask would not required during ion implantation.

Furthermore, in an embodiment, the p-base contact region can be simultaneously formed with an ESD process for ESD protection, such that a separate mask would not required during ion implantation.

Moreover, the p-type contact region can be lightly doped, to help increase current gain.

Additionally, because electrons are the majority carriers of the NPN bipolar transistor, superior mobility for better noise characteristics can be achieved versus a PNP bipolar transistor with holes as majority carriers.

Also, by using a bipolar transistor with superior flicker noise characteristics, the semiconductor device can be used in a device such as a voltage controlled oscillator (VCO) with favorable phase noise characteristics.

Any reference in this specification to “one embodiment,” “an embodiment,” “exemplary embodiment,” etc., means that a particular feature, structure, or characteristic described in connection with the embodiment is included in at least one embodiment of the disclosure. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with others of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a semiconductor substrate including an n-well;
an n-channel metal oxide semiconductor (nMOS) transistor on the semiconductor substrate separated from the n-well by a device isolation layer;
a p-base region on the n-well;
a base contact region and an emitter contact region on the p-base region; and
a collector contact region on the n-well;
wherein the emitter contact region comprises n-type ions, the collector contact region comprises n-type ions, the base contact region comprises p-type ions, and the p-base region comprises p-type ions.

2. The semiconductor device according to claim 1, wherein the p-base region comprises p-type ions at a low concentration.

3. The semiconductor device according to claim 1, wherein the emitter contact region is in electrical contact with the p-base region and the n-well to form an NPN bipolar transistor.

4. The semiconductor device according to claim 3, further comprising a dielectric on the nMOS transistor and the NPN bipolar transistor, wherein the dielectric comprises a contact connected to the base contact region, a contact connected to the emitter contact region, and a contact connected to the collector contact region.

5. The semiconductor device according to claim 1, further comprising a thermal oxide layer between the semiconductor substrate and the device isolation layer.

6. The semiconductor device according to claim 1, wherein a depth of the p-base region is larger than a depth of the base contact region and a depth of the emitter contact region.

7. The semiconductor device according to claim 6, wherein the depth of the p-base region is smaller than a depth of the n-well.

8. The semiconductor device according to claim 1, wherein a concentration of the p-type ions of the base contact region is higher than a concentration of the p-type ions of the p-base region.

9. A method for manufacturing a semiconductor device, comprising:
forming an n-well region on a semiconductor substrate;
forming a gate on the semiconductor substrate separated from the n-well region by a device isolation layer;
forming a p-type base contact region on the n-well region;
forming a source region and a drain region comprising n-type ions on the semiconductor substrate;
forming an n-type emitter contact region and n-type collector contact region on the n-well; and
forming a p-type p-base region on the n-well including on the base contact region and the emitter contact region.

10. The method according to claim 9, wherein the p-base region comprises p-type ions at a low concentration.

11. The method according to claim 9, wherein the gate, the source region, and the drain region form an NMOS transistor on the semiconductor substrate, and wherein the emitter contact region, the p-base region, and the n-well provide an NPN bipolar transistor.

12. The method according to claim 11, further comprising forming a dielectric and contacts on the nMOS transistor and the NPN bipolar transistor.

13. The method according to claim 9, wherein forming the source region and the drain region is performed simultaneously with forming the emitter contact region and the collector contact region using an ion implantation process.

14. The method according to claim 9, further comprising forming a thermal oxide layer between the semiconductor substrate and the device isolation layer.

15. The method according to claim 9, wherein the p-base region is formed to a depth greater than that of the base contact region and emitter contact region in the n-well.

16. The method according to claim 15, wherein the p-base region is formed to a depth shallower than that of the n-well.

17. The method according to claim 9, wherein a concentration of the p-type ions of the base contact region is higher than a concentration of the p-type ions of the p-base region.

18. The method according to claim 9, further comprising heat treating the semiconductor substrate after forming the p-base region on the n-well.

19. The method according to claim 9, further comprising forming a pMOS transistor.

20. The method according to claim 19, wherein the forming of the base contact region is simultaneously performed with a process of forming a source and drain region for the pMOS transistor.
